(19) United States
(12) Patent Application Publication
(10) Pub. No.: US 2026/0323878 A1
(43) Pub. Date: Oct. 15, 2026

(54) CRYOGENIC MODULE FOR USE IN A MODULAR CRYOGENIC INFRASTRUCTURE AND MODULAR CRYOGENIC INFRASTRUCTURE

(71) Applicant: kiutra GmbH, Munich (DE)

(72) Inventors: Jan Spallek, Munich (DE); Felix Rucker, Munich (DE)

(73) Assignee: kiutra GmbH, Munich (DE)

(21) Appl. No.: 19/465,354

(22) Filed: Jan. 30, 2026

Related U.S. Application Data
(63) Continuation of application No. PCT/EP2024/072265, filed on Aug. 6, 2024.

(30) Foreign Application Priority Data
Aug. 11, 2023 (EP) 23191209.8

(51) Int. Cl. H05K 7/20; F17C 13/08

(52) U.S. Cl. CPC H05K 7/20372; F17C 13/086; F17C 2205/0138; F17C 2205/0142

(57) ABSTRACT

A cryogenic module for use in a modular cryogenic infrastructure is provided. The cryogenic module has at least one first interface at an exterior of the cryogenic module, the at least one first interface is configured to detachably connect the cryogenic module to a pre-cooling module of the modular cryogenic infrastructure; and at least one second interface at the exterior of the cryogenic module, the at least one second interface is configured to detachably connect the cryogenic module to an operations module having operable equipment to be cooled by the cryogenic module.

### CROSS REFERENCE TO RELATED APPLICATIONS

This application is a continuation of International Application PCT/EP2024/072265 filed Aug. 6, 2024, which claims the benefit of EP Application 23191209.8 filed Aug. 11, 2023, the entire contents of both of which are incorporated herein by reference.

### BACKGROUND

### 1. Field of the Invention

The present disclosure relates to a cryogenic module for use in a modular cryogenic infrastructure, a modular cryogenic infrastructure, and a method of operating a modular cryogenic infrastructure. More particularly, the present disclosure relates to operating equipment, particularly electronics, inside an operations module under defined thermal conditions, e.g., at ultra-low temperatures in the sub-Kelvin or milli-Kelvin range.

### 2. Description of Related Art

A cryostat is generally used to achieve and maintain low temperatures. Low temperatures may be achieved by using, for example, a cryogenic fluid bath such as liquid helium. However, the cooling medium, such as liquid helium, continuously evaporates due to external and/or internal heat input in the cryostat and therefore needs to be refilled regularly. This requires considerable time and resources, whereby the operating costs of such cryostats are high.

To overcome the above drawbacks, cryogen-free cryostats have been developed. Cryogen-free cryostats may employ a cryogen-free closed cycle system, such a pulse tube cryocooler. Modern pulse tube cryocoolers can achieve temperatures down to 1.2K. To achieve sub-Kelvin temperatures, a magnetic cooling stage can be used in addition to the cryogen-free closed cycle system. The magnetic cooling stage may be an adiabatic demagnetization refrigerator (ADR), which can achieve temperatures down to a few milli-Kelvin. ADR is based on the magneto-caloric effect. When a medium is magnetized, its magnetic moments get aligned and the heat of magnetization is released. Vice versa, if the medium is demagnetized its temperature drops.

Cryostats have been used almost exclusively in scientific applications where power consumption, ease of use, uptime, and maintainability are valued much lower than performance, particularly cooling power and base temperature. With the proliferation of new commercial electronic hardware that requires cryostats to achieve operating conditions, these previously marginalized features will be critical to making new technologies scalable beyond the scientific laboratory.

In view of the above, new cryogenic modules, cryogenic infrastructures, and methods of operating such cryogenic modules and cryogenic infrastructures that overcome at least some of the problems in the art are beneficial.

### SUMMARY

It is an object of the present disclosure to provide a cryogenic module for use in a modular cryogenic infrastructure, a modular cryogenic infrastructure, and a method of operating a modular cryogenic infrastructure that enable efficient operation of equipment, such as electronics, at low temperatures. Another object of the present disclosure is to provide a scalable cryogenic infrastructure, and to reduce downtime and/or power consumption of the cryogenic infrastructure.

According to an independent aspect of the present disclosure, a cryogenic module for use in a modular cryogenic infrastructure is provided. The cryogenic module includes at least one first interface at an exterior of the cryogenic module, the at least one first interface configured to detachably connect the cryogenic module to a pre-cooling module; and at least one second interface at the exterior of the cryogenic module, the at least one second interface configured to detachably connect the cryogenic module to an operations module having operable equipment to be cooled by the cryogenic module.

The at least one operations module can be configured to operate the equipment for or during intended use (e.g., commercial use) and not for testing as in laboratories. The at least one operations module can include or accommodate any operable equipment, such as electronics, optics, or a combination thereof. Depending on the type of equipment, the at least one operations module can also be referred to as electronics module or optics module.

The cryogenic module can also be referred to as a “cryostat”. A cryostat is generally used to achieve and maintain low temperatures in the low-Kelvin and/or sub-Kelvin range.

According to some embodiments, which can be combined with other embodiments described herein, the cryogenic module and the pre-cooling module can be included (or implemented) in the same device. A “same device” in this context refers to a single piece of equipment or apparatus that integrates both the cryogenic module and the pre-cooling module, allowing them to function together.

According to some embodiments, which can be combined with other embodiments described herein, the cryogenic module is connectable to the pre-cooling module while the pre-cooling module is in a first operational state.

Preferably, the first operational state of the pre-cooling module is selected from the group including, or consisting of, an on-state and idle state of the pre-cooling module.

Preferably, a second operational state of the pre-cooling module is an off-state of the pre-cooling module.

According to some embodiments, which can be combined with other embodiments described herein, the cryogenic module is detachable from the pre-cooling module while the pre-cooling module is in the first operational state.

According to some embodiments, which can be combined with other embodiments described herein, the cryogenic module is connectable to the operations module while the cryogenic module is in a first operational state.

Preferably, the first operational state of the cryogenic module can be that an operating temperature of the cryogenic module corresponds to a temperature lower than room temperature, e.g., between 1.5 and 10K, such as 4K. In some embodiments, the operating temperature of the cryogenic module can be a temperature provided by the precooling module.

Additionally, or alternatively, the first operational state of the cryogenic module is selected from the group including, or consisting of, an on-state and idle state of the cryogenic module. In some embodiments, the idle state of the cryogenic module can correspond to an operating temperature between 1.5 and 10K, such as 4K, which may be a temperature provided by the pre-cooling module. The on-state may correspond to a temperature lower than that, such as IK or below.

Additionally, or alternatively, in the first operational state such as the idle state, the cryogenic module does not actively generate cooling power to maintain low temperatures, i.e., the means such as the pulse tube cryocooler or the magnetic cooling stage are not operated to generate cooling power. Additionally, in the first operational state such as the idle state, the cryogenic module may transfer cooling power from the pre-cooling module to the operations module (“passive cooling power”). In this case, the cryogenic module can only transfer part of the cooling power from the pre-cooling module to the operations module and use the remaining part of the cooling power to cool one or more internal thermal components thereof, such as heat shields.

Preferably, a second operational state of the cryogenic module is an off-state of the cryogenic module.

Preferably, in the second operational state of the cryogenic module, the cryogenic module does not actively generate cooling power and/or does not receive cooling power from another module and/or does not passively transfer cooling power to another module.

According to some embodiments, which can be combined with other embodiments described herein, the cryogenic module is detachable from the operations module while the cryogenic module is in the first operational state.

The terms “connectable” and “detachable” mean a releasable mechanical connection between the modules. For example, the modules can be connected to each other by positioning the modules, e.g., side by side or above each other, in a certain relative position and closing/fastening attachment means such as clamps and/or screws. Furthermore, the modules can be detached or disconnected from each other by opening/releasing the attachment means. Accordingly, “detachable” means that the modules can be separated without damaging the modules.

The connection between the modules may be any direct or indirect connection suitable for the connected modules to interact thermally and optionally electronically and/or optically and/or fluidly (e.g., a vacuum connection). For example, the connection may be a substantially vacuum-tight connection, e.g., using bellows, vacuum seals, rigid tubing, flexible tubing, O-rings, and the like.

The term “on-state” as used throughout the present disclosure refers to one of multiple operational states of the modules. In the on-state, the pre-cooling module or the cryogenic module may actively generate cooling power by operating means such as a pulse tube cryocooler or a magnetic cooling stage to maintain low temperatures. Furthermore, in the on-state, the operations module, particularly the electronics inside the operations module, is operated or switched on.

In the off-state, the pre-cooling module or the cryogenic module does not actively generate cooling power to maintain low temperatures, i.e., the means such as the pulse tube cryocooler or the magnetic cooling stage are not operated to generate cooling power. Furthermore, in the off-state, the operations module, particularly the electronics inside the operations module, is not operated or is switched off.

The term “idle state” as used throughout the present disclosure refers to an intermediate state between the on-state and the off-state.

Additionally, or alternatively, the idle state can be a state of the respective module in which the module is ready and/or pre-configured for actual operation in the on-state.

Additionally, or alternatively, in the idle state, the pre-cooling module and/or the cryogenic module may not actively generate cooling power, but at least some of its components may be operated or switched on so that the module is ready for operation in the on-state. Furthermore, in the idle state, the operations module, particularly the electronics inside the operations module, is ready for operation in the on-state.

Additionally, or alternatively, the module may be fully switched on and/or operational in the on-state, partially switched on and/or operational in the idle-state, and fully switched off and/or inoperable in the off-state.

Additionally, or alternatively, the idle state can be that an operating temperature of the module corresponds to a temperature lower than room temperature, e.g., between 1.5 and 10K, such as 4K. In some embodiments, the operating temperature of the module can be a temperature provided by the pre-cooling module. In the on-state, the operating temperature may be lower than that, such as IK or below.

According to some embodiments, which can be combined with other embodiments described herein, the pre-cooling module includes an interface arrangement compatible with the at least one first interface of the cryogenic module.

According to some embodiments, which can be combined with other embodiments described herein, the operations module includes an interface arrangement compatible with the at least one second interface of the cryogenic module.

According to some embodiments, which can be combined with other embodiments described herein, the at least one first interface of the cryogenic module includes at least one first thermal interface. The pre-cooling module may have a (first) thermal interface arrangement compatible with the at least one first thermal interface of the cryogenic module.

Preferably, the at least one first thermal interface is configured to be cooled by the pre-cooling module to a first temperature when the pre-cooling module is in the on-state, particularly via the (first) thermal interface arrangement.

Preferably, the first temperature is IK or above, or 4K or above. For example, the first temperature can be in a range between IK and 100K, or in a range between IK and 50K, or in a range between 4K and 100K, or in a range between 4K and 50K. In an exemplary embodiment, the first temperature can be about 4K or about 1.2K.

According to some embodiments, which can be combined with other embodiments described herein, the at least one first interface includes at least one first electrical interface. The pre-cooling module may have a (first) electrical interface arrangement compatible with the at least one first electrical interface of the cryogenic module. The electrical connection between the cryogenic module and the pre-cooling module may be configured for data communication, such as related to the operation and/or control of the cryogenic module and the pre-cooling module.

According to some embodiments, which can be combined with other embodiments described herein, the at least one first interface of the cryogenic module includes at least one first optical interface. The pre-cooling module may have a (first) optical interface arrangement compatible with the at least one first optical interface of the pre-cooling module. The optical connection between the cryogenic module and the precooling module may be configured for data communication, such as related to the operation and/or control of the cryogenic module and the pre-cooling module.

According to some embodiments, which can be combined with other embodiments described herein, the at least one second interface of the cryogenic module includes at least one second thermal interface. The operations module may have a (second) thermal interface arrangement compatible with the at least one second thermal interface of the cryogenic module.

Preferably, the at least one second thermal interface is configured to be cooled by a cooling mechanism of the cryogenic module to a second temperature, particularly when the cryogenic module is in the on-state.

Preferably, the second temperature is lower than the first temperature.

Preferably, the second temperature is 4K or below, or IK or below. For example, the second temperature can be in a range between IK and 4K, or in a range between l00 mK and 4K, or in a range between 2 mK and IK.

According to some embodiments, which can be combined with other embodiments described herein, the at least one second interface includes at least one second electrical interface. The operations module may have a (second) electrical interface arrangement compatible with the at least one second electrical interface of the cryogenic module. The electrical connection between the cryogenic module and the operations module may be configured for data communication, such as related to the operation and/or control of the cryogenic module and the operations module.

According to some embodiments, which can be combined with other embodiments described herein, the at least one second interface of the cryogenic module includes at least one second optical interface. The operations module may have a (second) optical interface arrangement compatible with the at least one second optical interface of the cryogenic module. The optical connection between the cryogenic module and the operations module may be configured for data communication, such as related to the operation and/or control of the cryogenic module and the operations module.

According to some embodiments, which can be combined with other embodiments described herein, the at least one second interface of the cryogenic module is a plurality of second interfaces. Accordingly, the cryogenic module can be connectable to multiple other modules via the second interfaces, such as other cryogenic modules and/or multiple operations modules.

According to some embodiments, which can be combined with other embodiments described herein, the cryogenic module is connectable to the operations module while being connected to the pre-cooling module. In other words, the operations module is connectable to the cryogenic module while the cryogenic module is already connected to the pre-cooling module.

According to some embodiments, which can be combined with other embodiments described herein, the cryogenic module is detachable from the operations module while being connected to the pre-cooling module. In other words, the operations module is detachable from the cryogenic module while the cryogenic module is still connected to the pre-cooling module.

According to some embodiments, which can be combined with other embodiments described herein, the cryogenic module is connectable to the operations module while the operations module is in a second operational state.

Preferably, the second operational state of the operations module is an off-state of the operations module. A first operational sate of the operations module may be selected from the group including, or consisting of, an idle state and an on-state.

According to some embodiments, which can be combined with other embodiments described herein, the cryogenic module is detachable from the operations module while the operations module is in the second operational state. In other words, the operations module is detachable from the cryogenic module while the operations module is in the off-state.

According to some embodiments, which can be combined with other embodiments described herein, the cryogenic module is connectable to the pre-cooling module while being connected to the operations module. In other words, the pre-cooling module is connectable to the cryogenic module while the cryogenic module is already connected to the operations module.

According to some embodiments, which can be combined with other embodiments described herein, the cryogenic module is detachable from the pre-cooling module while being connected to the operations module. In other words, the pre-cooling module is detachable from the cryogenic module while the operations module is still connected to the cryogenic module.

According to some embodiments, which can be combined with other embodiments described herein, the cryogenic module is connectable to the pre-cooling module while being in the second operational state, i.e., the off-state.

According to some embodiments, which can be combined with other embodiments described herein, the cryogenic module is detachable from the pre-cooling module while being in the second operational state, i.e., the off-state.

According to some embodiments, which can be combined with other embodiments described herein, the cryogenic module includes a heater arrangement at the at least one first interface and/or at least one second interface configured to heat the at least one first interface and/or at least one second interface. For example, if an operations module is disconnected from the cryogenic module, the load reduction can be compensated using the heater arrangement, stabilizing operation of the cryogenic module.

According to another independent aspect of the present disclosure, a modular cryogenic infrastructure is provided. The modular cryogenic infrastructure includes at least one cryogenic module; a pre-cooling module; and at least one operations module. The cryogenic module may be the cryogenic module described above.

According to some embodiments, which can be combined with other embodiments described herein, the modular cryogenic infrastructure is scalable.

According to some embodiments, which can be combined with other embodiments described herein, multiple cryogenic modules are connectable (or connected) in parallel to the pre-cooling module. In particular, multiple cryogenic modules can be connectable (or connected) to the same pre-cooling module.

Preferably, the pre-cooling module has a plurality of (first) thermal interface arrangements, with one cryogenic module connectable to each of the thermal interface arrangements.

Optionally, the pre-cooling module has a plurality of (first) electrical interface arrangements, with one cryogenic module connectable to each of the electrical interface arrangements. Additionally, or alternatively, the pre-cooling module has a plurality of (first) optical interface arrangements, with one cryogenic module connectable to each of the optical interface arrangements.

Preferably, the multiple cryogenic modules are connectable (or connected) to the pre-cooling module at the same time.

Preferably, the pre-cooling module is configured to simultaneously supply cooling power to the multiple cryogenic modules.

According to some embodiments, which can be combined with other embodiments described herein, at least two operations modules are connectable (or connected) to each other via respective interfaces, such as thermal and/or electrical and/or optical interfaces.

According to some embodiments, which can be combined with other embodiments described herein, the at least two operations modules include a first operations module and a second operations module, wherein the first operations module is connectable (or connected) to the second operations module.

Preferably, the first operations module of the at least two operations modules is connectable (or connected) to a first cryogenic module.

In some embodiments, the second operations module is connectable (or connected) to a second cryogenic module.

In other embodiments, the second operations module of the at least two operations modules is connectable (or connected) to the first operations module while being not connected to a cryogenic module. In particular, the second operations module is not connectable (or connected) to any cryogenic module. For example, the pre-cooling module, the first cryogenic module, the first operations module and the second operations module may be connectable (or connected) in series. In this case, cooling power may be provided to the second operations module by the first cryogenic module via the first operations module.

According to some embodiments, which can be combined with other embodiments described herein, the at least one operations module is, or includes, a quantum technology module, particularly a quantum computing module, a quantum communications module, a quantum sensing module, an optics module, or a combination thereof.

According to some embodiments, which can be combined with other embodiments described herein, the at least one cryogenic module is, or includes, an adiabatic demagnetization refrigeration module.

According to some embodiments, which can be combined with other embodiments described herein, the pre-cooling module is, or includes, a centralized precooling module.

According to some embodiments, which can be combined with other embodiments described herein, the pre-cooling module is, or includes, a Turbo-Brayton cooling module.

Preferably, the pre-cooling module is part of a commercial setup, such as a data center.

According to some embodiments, which can be combined with other embodiments described herein, the modular cryogenic infrastructure is, or is included in, a data center.

According to some embodiments, which can be combined with other embodiments described herein, the modular cryogenic infrastructure is, or is included in, a commercial setup.

According to some embodiments, which can be combined with other embodiments described herein, the modular cryogenic infrastructure includes a user interface.

Preferably, the user interface includes at least one display unit and at least one input unit, such as a keyboard. In some embodiments, the user interface includes a touch screen.

Preferably, the user interface is configured to allow a user to control operation of the modular cryogenic infrastructure.

Preferably, the user interface is configured to inform and/or guide a user during a module connecting process and/or a module disconnecting process.

Preferably, the user interface may be configured to guide the user through the individual steps of the module connecting process and/or module disconnecting process.

Preferably, the user interface may be configured to receive user input about process steps completed by the user, such as attaching screws and/or clamps. Upon receiving the user input, the user interface may inform the user of the next step(s) of the module connecting process and/or module disconnecting process.

According to another independent aspect of the present disclosure, a pre-cooling module for use in a modular cryogenic infrastructure is provided. The modular cryogenic infrastructure may be the modular cryogenic infrastructure of the embodiments of the present disclosure.

According to some embodiments, which can be combined with other embodiments described herein, the pre-cooling module includes an interface arrangement at an exterior of the pre-cooling module, the interface arrangement configured to detachably connect the pre-cooling module to one or more cryogenic modules and/or one or more operations modules of the cryogenic infrastructure, wherein the pre-cooling module is connectable to the one or more cryogenic modules and/or the one or more operations modules and/or detachable from the one or more cryogenic modules and/or the one or more operations modules while the pre-cooling module is in a first operational state.

Preferably, the first operational state of the pre-cooling module is selected from the group including, or consisting of, an on-state and idle state of the pre-cooling module.

According to some embodiments, which can be combined with other embodiments described herein, the pre-cooling module includes a heater arrangement at the (thermal) interface arrangement configured to heat the (thermal) interface arrangement. For example, if a cryogenic module is disconnected from the pre-cooling module, the load reduction can be compensated using the heater arrangement, stabilizing operation of the pre-cooling module.

According to another independent aspect of the present disclosure, an operations module for use in a modular cryogenic infrastructure is provided. The modular cryogenic infrastructure may be the modular cryogenic infrastructure of the embodiments of the present disclosure.

According to some embodiments, which can be combined with other embodiments described herein, the operations module includes an interface arrangement at an exterior of the operations module, the interface arrangement configured to detachably connect the operations module to a pre-cooling module of the cryogenic infrastructure, wherein the operations module is connectable to the pre-cooling module and/or detachable from the pre-cooling module while the pre-cooling module is in a first operational state.

Preferably, the first operational state of the pre-cooling module is selected from the group including, or consisting of, an on-state and idle state of the pre-cooling module.

According to another independent aspect of the present disclosure, an operations module for use in a modular cryogenic infrastructure is provided. The modular cryogenic infrastructure may be the modular cryogenic infrastructure of the embodiments of the present disclosure.

According to some embodiments, which can be combined with other embodiments described herein, the operations module includes an interface arrangement at an exterior of the operations module, the interface arrangement configured to detachably connect the operations module to at least one cooling module of the cryogenic infrastructure.

According to some embodiments, which can be combined with other embodiments described herein, the operations module can be configured according to any of the embodiments described herein.

According to some embodiments, which can be combined with other embodiments described herein, the at least one cooling module includes a pre-cooling module and/or a cryogenic module. The pre-cooling module and/or a cryogenic module can be configured according to any of the embodiments described herein.

According to some embodiments, which can be combined with other embodiments described herein, wherein the operations module is connectable to the at least one cooling module and/or detachable from the at least one cooling module while the at least one cooling module is in a first operational state.

Preferably, the first operational state of the at least one cooling module is an on-state or idle state.

According to another independent aspect of the present disclosure, a method of operating a modular cryogenic infrastructure is provided. The method may use the modular cryogenic infrastructure of the embodiments of the present disclosure.

According to some embodiments, which can be combined with other embodiments described herein, the method includes connecting the cryogenic module to the pre-cooling module while the pre-cooling module is in a first operational state.

Preferably, the first operational state of the pre-cooling module is selected from the group including, or consisting of, an on-state and idle state of the pre-cooling module.

According to some embodiments, which can be combined with other embodiments described herein, the method includes detaching the cryogenic module from the pre-cooling module while the pre-cooling module is in the first operational state.

According to some embodiments, which can be combined with other embodiments described herein, the method includes connecting the cryogenic module to the operations module while the cryogenic module is in a first operational state.

Preferably, the first operational state of the cryogenic module is selected from the group including, or consisting of, an on-state and idle state of the cryogenic module.

According to some embodiments, which can be combined with other embodiments described herein, the method includes detaching the cryogenic module from the operations module while the cryogenic module is in the first operational state.

According to another independent aspect of the present disclosure, a cryogenic infrastructure is provided. The cryogenic infrastructure includes a pre-cooling module, an operations module connectable to the pre-cooling module; and one or more cryogenic modules connectable to the operations module.

The cryogenic infrastructure may be the modular cryogenic infrastructure described throughout this document. Additionally, or alternatively, the pre-cooling module may be the pre-cooling module described throughout this document. Additionally, or alternatively, the operations module may be the operations module described throughout this document. Additionally, or alternatively, the cryogenic module may be the cryogenic module described throughout this document.

According to some embodiments, which can be combined with other embodiments described herein, the pre-cooling module may be a single pre-cooling module.

According to some embodiments, which can be combined with other embodiments described herein, the operations module may be a single operations module.

According to some embodiments, which can be combined with other embodiments described herein, the operations module has operable equipment to be cooled by the cryogenic module.

According to some embodiments, which can be combined with other embodiments described herein, the operations module is configured to provide a thermal path between the pre-cooling module and the one or more cryogenic modules to provide pre-cooling to the one or more cryogenic modules. Accordingly, the one or more cryogenic modules may provide cooling power to the operations module to cool the operable equipment (e.g., IK or below), and may receive pre-cooling power (e.g., 4K) from the pre-cooling module via the same operations module. In other words, there may be a two-way thermal path between the operations module and the one or more cryogenic modules. The two-way thermal path may be implemented using, for example, nested thermal interfaces.

According to some embodiments, which can be combined with other embodiments described herein, the operations module is configured to cool one or more internal thermal components thereof using the pre-cooling power received from the precooling module. Accordingly, the pre-cooling power may be used not only by the one or more cryogenic modules but may also be used by the operations module to cool the one or more internal thermal components thereof, such as thermal shields.

Preferably, the operations module may transfer cooling power from the precooling module to the one or more cryogenic modules (“passive cooling power”). For example, the operations module can only transfer part of the cooling power from the precooling module to the one or more cryogenic modules and use the remaining part of the cooling power to cool one or more internal thermal components thereof, such as heat shields.

Further aspects, benefits, and features of the present disclosure are apparent from the claims, the description, and the accompanying drawings.

### DESCRIPTION OF THE DRAWINGS

So that the manner in which the above recited features of the present disclosure can be understood in detail, a more particular description of the disclosure, briefly summarized above, may be had by reference to embodiments. The accompanying drawings relate to embodiments of the disclosure and are described in the following:

FIG. 1 shows a schematic view of a modular cryogenic infrastructure in an assembled state according to the embodiments of the present disclosure;

FIG. 2 shows a schematic view of a modular cryogenic infrastructure in an disassembled state according to the embodiments of the present disclosure;

FIG. 3 shows a schematic view of a modular cryogenic infrastructure in an disassembled state according to further embodiments of the present disclosure;

FIG. 4 shows a schematic view of a modular cryogenic infrastructure according to embodiments of the present disclosure;

FIG. 5 shows a schematic view of a modular cryogenic infrastructure according to further embodiments of the present disclosure;

FIG. 6 shows a schematic view of a modular cryogenic infrastructure according to further embodiments of the present disclosure; and

FIG. 7 shows a schematic view of a modular cryogenic infrastructure according to further embodiments of the present disclosure.

### DETAILED DESCRIPTION

Reference will now be made in detail to the various embodiments of the disclosure, one or more examples of which are illustrated in the figures. Within the following description of the drawings, the same reference numbers refer to same components. Generally, only the differences with respect to individual embodiments are described. Each example is provided by way of explanation of the disclosure and is not meant as a limitation of the disclosure. Further, features illustrated or described as part of one embodiment can be used on or in conjunction with other embodiments to yield yet a further embodiment. It is intended that the description includes such modifications and variations.

Cryostats have been used almost exclusively in scientific applications where power consumption, ease of use, uptime, and maintainability are valued much lower than performance, particularly cooling power and base temperature. With the proliferation of new commercial electronic hardware that requires cryostats to achieve operating conditions, these previously marginalized features will be critical to making new technologies scalable beyond the scientific laboratory.

The embodiments of the present disclosure overcome the above drawbacks by providing a modular cryogenic infrastructure having a centralized pre-cooling mechanism and independently operable modules. This allows the cryogenic infrastructure to be both flexible and scalable beyond the scientific laboratory, making it suitable for large facilities such as data centers. In addition, the modularity does not require complete shutdown of the cryogenic infrastructure for maintenance, repair, and addition of more cryogenic and/or operations modules.

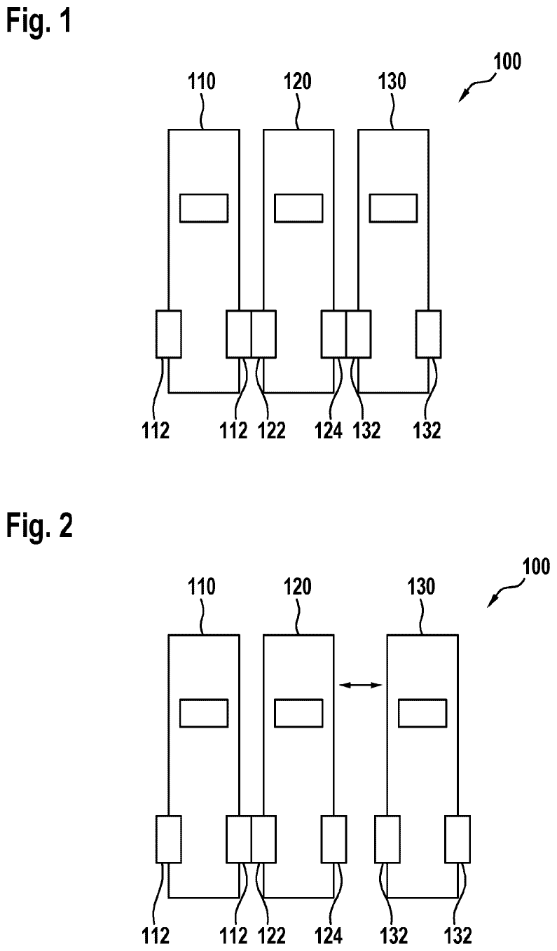

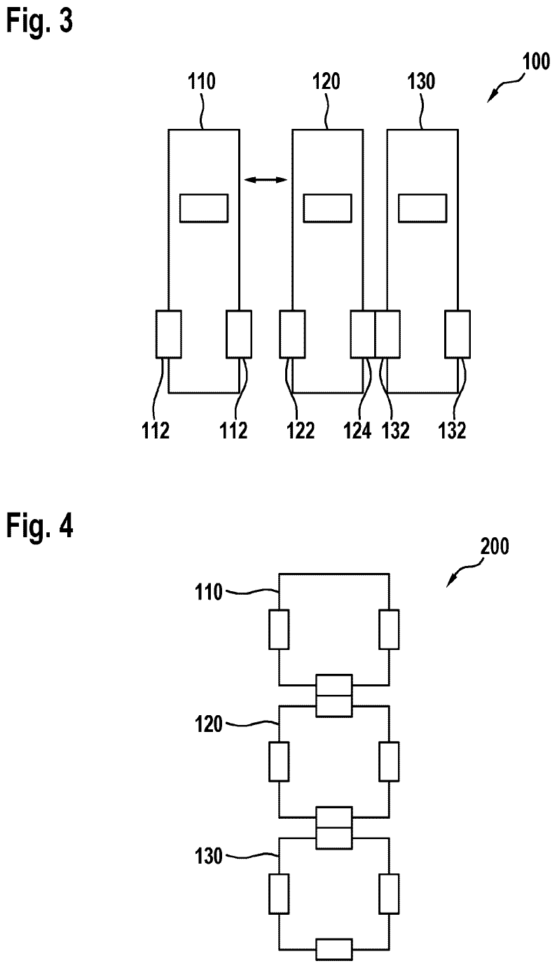

FIG. 1 shows a schematic view of a modular cryogenic infrastructure 100 in an assembled state according to the embodiments of the present disclosure. FIG. 2 shows a schematic view of the modular cryogenic infrastructure 100 in a partly disassembled state. FIG. 3 shows a schematic view of the modular cryogenic infrastructure 100 in another partly disassembled state.

The modular cryogenic infrastructure 100 can be used to operate equipment, such as quantum technology, under defined thermal conditions, e.g., at ultra-low temperatures in the sub-Kelvin or milli-Kelvin range.

According to some non-limiting embodiments of the present disclosure, the modular cryogenic infrastructure 100 is, or is included in, a commercial setup, such as a data center.

The modular cryogenic infrastructure 100 includes a pre-cooling module 110, at least one cryogenic module 120, and at least one operations module 130.

The pre-cooling module 110 may be a centralized pre-cooling module, such as a Turbo-Brayton cooling module. The single centralized pre-cooling module, such as the such as a Turbo-Brayton cooling module, can be implemented on an industrial scale, reducing power consumption.

The at least one cryogenic module 120 may be an adiabatic demagnetization refrigeration (ADR) module. In some embodiments, the adiabatic demagnetization refrigeration (ADR) module can achieve and maintain low temperatures in the low-Kelvin and/or sub-Kelvin range using the magneto-caloric effect.

The operations module 130, which can also be referred to as a payload module, has operable equipment, such as electronics and/or optics, to be cooled by the cryogenic module 120. The at least one operations module 130 may be a quantum technology module, such as a quantum computing module, a quantum communications module and/or a quantum sensing module. In particular, the at least one operations module 130 can be configured to operate the quantum technology for intended use (e.g., commercial use) and not for testing as in laboratories. In other words, the operable electronics to be cooled by the cryogenic module 120 may be quantum electronics, such as a quantum computer.

In some embodiments, an operations module can be understood as a component or module that includes all necessary elements for the operation and/or control and/or testing of a sample, device, chip etc., specifically configured to interface with one or more cryogenic modules and/or one or more pre-cooling modules to achieve and maintain different temperatures. The operations module is essentially a self-contained unit designed to support and operate e.g. a quantum chip or similar device, ensuring all necessary conditions and controls are in place, except for the provision of low temperatures, which is handled by the cryogenic module and/or pre-cooling module.

Features of the operations module may include, but are not limited to:
different temperature stages that can be interfaced to respective stages in cooling module; and/or
staggered implementation of thermal stages and radiation shields to thermalize control wiring, support structures and/or electronics to bespoke intermediate temperature stages, in particular to minimize thermal noise on object/sample/device/chip to be operated and/or tested and/or minimize heat load on individual temperature stages; and/or
object/sample/device/chip to be operated and/or tested; and/or
object/sample/device/chip socket and/or holder; and/or
control wiring for operation and/or testing of object/sample/device/chip; and/or
auxiliary electronics for control or readout of object/sample/device/chip; and/or
shielding for magnetic and/or electric fields; and/or • vacuum and/or radiation shields; and/or
diagnostic and/or control devices (e.g., sensors (e.g., thermometers), heaters, active field cancellation devices etc.); and/or
room temperature control electronics; and/or
essentially everything that is needed for operation of e.g. a quantum chip except the generation of low temperatures.

The individual modules 120, 130 may take the shape of 19″ racks and provide interfaces between these racks to facilitate connection and disconnection of individual modules without interfering with the operation of the previous module(s). These interfaces may allow interfacing of individual vacuums, temperatures, and/or electrical signals.

In the example of FIG. 1, the pre-cooling module 110, the cryogenic module 120, and the operations module 130 are each in a first operational state, such as an on-state or idle state. A second operational state of the pre-cooling module 110, the cryogenic module 120, and the operations module 130 may be an off-state.

The term “on-state” as used throughout the present disclosure refers to an actual operating state of the respective module. Similarly, the term “off-state” as used throughout the present disclosure refers to a non-operating state of the respective module. For example, in the on-state, the pre-cooling module 110 may actively generate cooling power by operating for instance a Turbo-Brayton mechanism. In the off-state, the precooling module 110 may not operate for instance the Turbo-Brayton mechanism to generate cooling power. The idle state is an intermediate state between the on-state and the off-state in which the module is ready for actual operation.

The cryogenic module 120 includes at least one first interface 122 at an exterior of the cryogenic module 120, the at least one first interface 122 configured to detachably connect the cryogenic module 120 to the pre-cooling module 110; and at least one second interface 124 at the exterior of the cryogenic module 120, the at least one second interface 124 configured to detachably connect the cryogenic module 120 to the operations module 130 having operable equipment to be cooled by the cryogenic module 120.

The pre-cooling module 110 includes an interface arrangement 112 compatible with the at least one first interface 122 of the cryogenic module 120.

In some embodiments, the at least one first interface 122 of the cryogenic module 120 may include at least one first thermal interface, and the interface arrangement 112 of the pre-cooling module 110 may have a thermal interface arrangement compatible with the at least one first thermal interface of the cryogenic module 120.

The at least one first thermal interface of the cryogenic module 120 may be configured to be cooled by the pre-cooling module 110 to a first temperature when the pre-cooling module 110 is in the on-state. In some embodiments, the first temperature can be IK or above, or 4K or above. For example, the first temperature can be in a range between IK and 100K, or in a range between IK and 50K, or in a range between 4K and 100K, or in a range between 4K and 50K. In an exemplary embodiment, the first temperature can be about 4K or about 1.2K.

In some embodiments, the at least one first interface 122 of the cryogenic module 120 may include at least one first electrical interface, and the interface arrangement 112 of the pre-cooling module 110 may have an electrical interface arrangement compatible with the at least one first electrical interface of the cryogenic module 120. The electrical connection between the cryogenic module 120 and the precooling module 110 may be configured for data communication, such as related to the operation and/or control of the cryogenic module 120 and the pre-cooling module 110.

In some embodiments, the at least one first interface 122 of the cryogenic module 120 may include at least one first optical interface, and the interface arrangement 112 of the pre-cooling module 110 may have an optical interface arrangement compatible with the at least one first optical interface of the cryogenic module 120. The optical connection between the cryogenic module 120 and the pre-cooling module 110 may be configured for data communication, such as related to the operation and/or control of the cryogenic module 120 and the pre-cooling module 110.

The operations module 130 includes an interface arrangement 132 compatible with the at least one second interface 124 of the cryogenic module 120.

In some embodiments, the at least one second interface 124 of the cryogenic module 120 may include at least one second thermal interface, and the interface arrangement 132 of the operations module 130 may have a thermal interface arrangement compatible with the at least one second thermal interface of the cryogenic module 120.

The at least one second thermal interface of the cryogenic module 120 may be configured to be cooled by a cooling mechanism of the cryogenic module 120 to a second temperature lower than the first temperature when the cryogenic module 120 is in the on-state. The second temperature may be 4K or below, or IK or below. For example, the second temperature can be in a range between IK and 4K, or in a range between l00mK and 4K, or in a range between l00mK and IK.

In some embodiments, the at least one second interface 124 of the cryogenic module 120 may include at least one second electrical interface, and the interface arrangement 132 of the operations module 130 may have an electrical interface arrangement compatible with the at least one second electrical interface of the cryogenic module 120. The electrical connection between the cryogenic module 120 and the operations module 130 may be configured for data communication, such as related to the operation and/or control of the cryogenic module 120 and the operations module 130.

In some embodiments, the at least one second interface 124 of the cryogenic module 120 may include at least one second optical interface, and the interface arrangement 132 of the operations module 130 may have an optical interface arrangement compatible with the at least one second optical interface of the cryogenic module 120. The optical connection between the cryogenic module 120 and the operations module 130 may be configured for data communication, such as related to the operation and/or control of the cryogenic module 120 and the operations module 130.

As shown in the example of FIG. 2, in some embodiments, the cryogenic module 120 and the operations module 130 can be connected to each other while the cryogenic module 120 is in the first operational state, such as the on-state or idle state, and optionally while the pre-cooling module 110 is in the first operational state, such as the on-state or idle state, and/or the operations module 130 is in the second operational state which is the off-state. In addition, the cryogenic module 120 and the operations module 130 can be separated from each other while the cryogenic module 120 is in the first operational state, and optionally while the pre-cooling module 110 is in the first operational state and/or the operations module 130 is in the second operational state.

Additionally, or alternatively, the cryogenic module 120 and the operations module 130 can be connected to each other while the cryogenic module 120 is already connected to the pre-cooling module 110. In addition, the cryogenic module 120 and the operations module 130 can be separated from each other while the cryogenic module 120 is still connected to the pre-cooling module 110.

As shown in the example of FIG. 3, in some embodiments, the cryogenic module 120 and the pre-cooling module 110 can be connected to each other while the pre-cooling module 110 is in the first operational state, such as the on-state or idle state, and optionally while the cryogenic module 120 is in the second operational state (off-state) and/or the operations module 130 is in the second operational state (off-state). In addition, the cryogenic module 120 and the pre-cooling module 110 can be separated from each other while the pre-cooling module 110 is in the first operational state (on-state or idle state), and optionally while the cryogenic module 120 is in the off-state and/or the operations module 130 is in the second operational state (off-state).

Additionally, or alternatively, the cryogenic module 120 and the pre-cooling module 110 can be connected to each other while the cryogenic module 120 is already connected to the operations module 130. In addition, the cryogenic module 120 and the pre-cooling module 110 can be separated from each other while the cryogenic module 120 is still connected to the operations module 130.

In view of the above, there is a releasable mechanical connection between the modules 110, 120 and 130. For example, the modules 110, 120 and 130 can be connected to each other by positioning the modules 110, 120 and 130 side by side and/or above each other in a certain relative position and optionally closing/fastening attachment means such as clamps and/or screws. Furthermore, the modules 110, 120 and 130 can be separated from each other by opening/releasing the attachment means. Accordingly, “detachable” means that the modules 110, 120 and 130 can be separated without damaging the modules 110, 120 and 130.

The connection between the modules 110, 120 and 130 may be any direct or indirect connection suitable for the connected modules to interact thermally and optionally electronically and/or optically.

In some embodiments, the connection may be a substantially vacuum-tight connection.

Optionally, one or more vacuum locks can be provided to maintain a vacuum in one or more areas of the modular cryogenic infrastructure during adding and/or removing modules. For example, the one or more vacuum locks can be configured to maintain a vacuum in modules which are in the first operational state, such as the on-state or idle state. Optionally, the one or more vacuum locks can be configured to maintain a vacuum in modules which are in the second operational state, i.e., the off-state.

Optionally, the vacuum itself may be used to secure the connection between the modules. Optionally, fastening means can be used to secure the connection between the modules, such as a plug-connection using male and female plugs, a screw connection, a Bayonet lock, a latch connection, and the like.

Optionally, stabilizing means can be provided to stabilize an assembling process of two modules. For example, a pneumatic device and/or a guiding device can be used so that surfaces are slowly brought together when a vacuum is generated.

Optionally, first certain parts of the modules may be brought together to thermally and optionally electrically connect the modules, and then a vacuum may be generated in at least one of the modules and/or the fastening means may be fastened to securely connect the modules and prevent vacuum leaks.

Optionally, electrical confirmation means, such as one or more pins, can be provided at the modules. If the electrical connection (and thus the thermal connection) between the modules is correctly established, a current flowing through the one or more pins may indicate the connection. For example, the one or more pins can be provided at the electric interface.

In some embodiments, the connection may include a flexible tube, such as a bellows tube. The flexible tube provides flexibility such that the relative position between the modules can vary in a certain range. The thermal interface can be arranged inside the flexible tube. Optionally, the electrical interface and/or optical interface can be arranged inside the flexible tube. In this case, the electrical interface and/or optical interface can be thermalized. Alternatively, the electrical interface and/or optical interface can be arranged outside the flexible tube. In this case, the electrical interface and/or optical interface may not be thermalized. This is particularly useful if no (pre-)cooling of the electrical interface and/or optical interface is required.

Optionally, one or more thermal shields and/or spacer means to separate different components and/or temperature regimes from each other can be arranged inside the flexible tube. For example, a milli-Kelvin bus, a 4K shield, a 40K shield, and a vacuum vessel can be arranged in this order from the inside out, with spaces in between so that no contact occurs. A stabilizing connection, such as the spacer means, between these “layers” can have a low thermal conductivity (e.g., due to a small diameter) to minimize thermal interaction between different temperature regimes.

Optionally, three or more flexible tubes can be connected to each other e.g. at an intersection or crossing device. For example, a first flexible tube may be connected to the pre-cooling module and the intersection or crossing device, and two or more second flexible tubes can be connected to the intersection or crossing device and corresponding two or more cryogenic modules. A similar connection can be provided between one or more cryogenic modules and one or more operations modules.

In other embodiments, the connection may include a rigid tube. The thermal interface can be arranged inside the rigid tube. Optionally, the electrical interface and/or optical interface can be arranged inside the rigid tube. In this case, the electrical interface and/or optical interface can be thermalized. Alternatively, the electrical interface and/or optical interface can be arranged outside the rigid tube. In this case, the electrical interface and/or optical interface may not be thermalized. This is particularly useful if no (pre-) cooling of the electrical interface and/or optical interface is required.

Optionally, one or more thermal shields and/or spacer means to separate different components and/or temperature regimes from each other can be arranged inside the rigid tube. For example, a milli-Kelvin bus, a 4K shield, a 40K shield, and a vacuum vessel can be arranged in this order from the inside out, with spaces in between so that no contact occurs. A stabilizing connection, such as the spacer means, between these “layers” can have a low thermal conductivity (e.g., due to a small diameter) to minimize thermal interaction between different temperature regimes. Due to the rigidity of the tube, the spaces between the “layers” can be small, which allows a compact design to be achieved.

Optionally, three or more rigid tubes can be connected to each other e.g. at an intersection or crossing device. For example, a first rigid tube may be connected to the pre-cooling module and the intersection or crossing device, and two or more second rigid tubes can be connected to the intersection or crossing device and corresponding two or more cryogenic modules. A similar connection can be provided between one or more cryogenic modules and one or more operations modules.

FIG. 4 shows a schematic view of a modular cryogenic infrastructure 200 according to embodiments of the present disclosure. The cryogenic infrastructure 200 is similar to the cryogenic infrastructure shown in FIGS. 1 to 3, and therefore a description of similar or identical aspects is not repeated.

The cryogenic infrastructure 200 is scalable. The term “scalable” means that multiple cryogenic modules and/or multiple operations modules can be connected to each other and/or to the single pre-cooling module 110 in various ways. To this end, the modules 110, 120 and 130 may each have multiple interfaces for connecting the modules 110, 120 and 130.

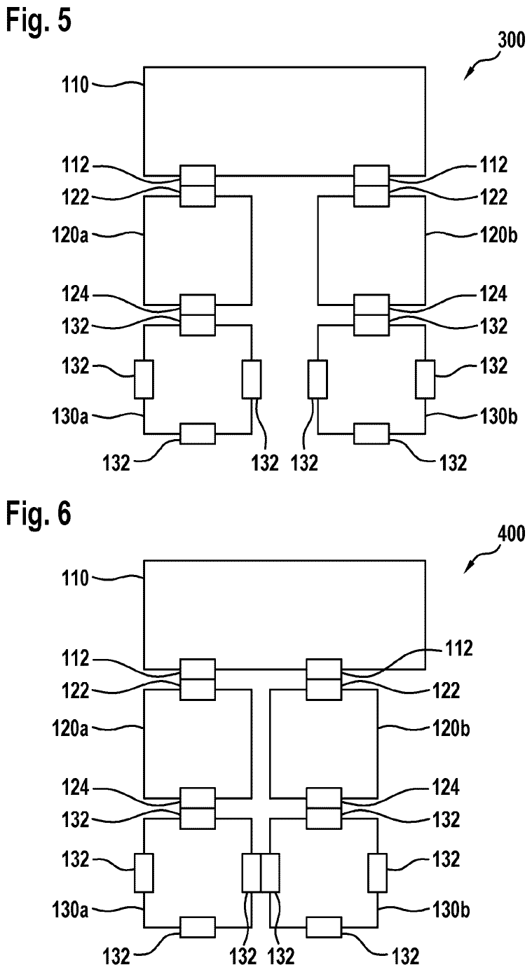

FIG. 5 shows a schematic view of a modular cryogenic infrastructure 300 according to further embodiments of the present disclosure. The cryogenic infrastructure 300 is similar to the cryogenic infrastructures shown in FIGS. 1 to 4, and therefore a description of similar or identical aspects is not repeated.

In some embodiments, the pre-cooling module 110 has a plurality of interface arrangements 112, with one cryogenic module 120a, 120b connectable to each of the interface arrangements 112.

As shown in FIG. 5, multiple cryogenic modules 120a, 120b can be connected in parallel to the single pre-cooling module 110. Preferably, the multiple cryogenic modules 120a, 120b are connected to the pre-cooling module 110 at the same time and are simultaneously supplied with cooling power from the pre-cooling module 110.

In addition, multiple operations modules 130a, 130b can be provided, wherein each operations module 130a, 130b can be connected to a respective cryogenic module 120a, 120b. In the example of FIG. 5, a first operations module 130a is connected to a first cryogenic module 120a, and a second operations module 130b is connected to a second cryogenic module 120b.

Although two cryogenic modules and two operations modules are shown in the example of FIG. 5, it is to be understood that the present disclosure is not limited thereto, and that a different number of cryogenic modules and operations modules may be simultaneously connected to the pre-cooling module and/or to each other. In particular, the number of cryogenic modules and the number of operations modules simultaneously connected to the pre-cooling module and/or to each other may be the same or different.

In some embodiments, the number of cryogenic modules can be two or more, five or more, 10 or more, 20 or more, 50 or more, or 100 or more.

Additionally, or alternatively, the number of operations modules can be two or more, five or more, 10 or more, 20 or more, 50 or more, or 100 or more.

FIG. 6 shows a schematic view of a modular cryogenic infrastructure 400 according to further embodiments of the present disclosure. The cryogenic infrastructure 400 is similar to the cryogenic infrastructures shown in FIGS. 1 to 5, and therefore a description of similar or identical aspects is not repeated.

In some embodiments, at least two adjacent operations modules 130a, 130b are connected to each other via respective interfaces 132, such as thermal interfaces and/or electrical interfaces and/or optical interfaces.

The connection between the at least two operations modules 130a, 130b may be configured for thermal transfer between the at least two operations modules 130a, 130b. Additionally, or alternatively, the connection between the at least two operations modules 130a, 130b may be configured for data communication, such as related to the operation and/or control of the at least two operations modules 130a, 130b.

In the example of FIG. 6, the at least two operations modules include a first operations module 130a and a second operations module 130b, wherein the first operations module 130a is connected to the second operations module 130b. The first operations module 130a is connected to the first cryogenic module 120a and the second operations module 130b is connected to the second cryogenic module 120b.

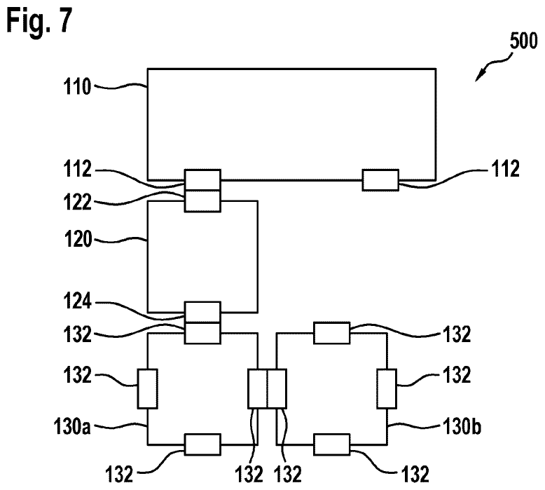

FIG. 7 shows a schematic view of a modular cryogenic infrastructure 500 according to further embodiments of the present disclosure. The cryogenic infrastructure 500 is similar to the cryogenic infrastructures shown in FIGS. 1 to 6, and therefore a description of similar or identical aspects is not repeated.

In the example of FIG. 7, the second operations module 130b is connected to the first operations module 130a while being not connected to a cryogenic module. In particular, the second operations module 130b may not be connected to any cryogenic module. For example, the pre-cooling module 110, the cryogenic module 120, the first operations module 130a and the second operations module 130b may be connected in series. In this case, cooling power may be provided to the second operations module 130b by the cryogenic module 120 via the first operations module 130a and the respective interfaces 124 and 132.

In view of the above, the embodiments of the present disclosure provide a modular cryogenic infrastructure having a centralized pre-cooling mechanism and independently operable modules. This allows the cryogenic infrastructure to be both flexible and scalable beyond the scientific laboratory, making it suitable for large facilities such as data centers. In addition, the modularity does not require complete shutdown of the cryogenic infrastructure for maintenance, repair, and addition of more cryogenic and/or operations modules.

While the foregoing is directed to embodiments of the disclosure, other and further embodiments of the disclosure may be devised without departing from the basic scope thereof, and the scope thereof is determined by the claims that follow.

What is claimed is:

1. A cryogenic module for use in a modular cryogenic infrastructure, comprising:
a first interface at an exterior of the cryogenic module, the first interface being configured to connect and disconnect the cryogenic module to/from a pre-cooling module of the cryogenic infrastructure while the pre-cooling module is in an on-state or idle state; and
a second interface at the exterior of the cryogenic module, the second interface being configured to connect and disconnect the cryogenic module to/from an operations module having operable equipment to be cooled by the cryogenic module while the cryogenic module is in an on-state or idle state.

2. The cryogenic module of claim 1, wherein the first and second interfaces comprise an interface selected from a group consisting of a thermal interface, an electrical interface, an optical interface, and any combinations thereof.

3. The cryogenic module of claim 1, wherein the first and second interfaces are configured so that the second interface connects and disconnects the cryogenic module to/from the operations module while the first interface connects the cryogenic module to the pre-cooling module.

4. The cryogenic module of claim 3, wherein the second interface is configured to connect and disconnect the cryogenic module to/from the operations module while the cryogenic module is in an off-state.

5. The cryogenic module of claim 1, wherein the first and second interfaces are configured so that the first interface connects and disconnects the cryogenic module to/from the pre-cooling module while the second interface connects the cryogenic module to the operations module.

6. The cryogenic module of claim 5, wherein the first interface is configured to connect and disconnect the cryogenic module to/from the pre-cooling module while the cryogenic module is in an off-state.

7. A modular cryogenic infrastructure, comprising:
a cryogenic module having a first interface and a second interface at an exterior of the cryogenic module;
a pre-cooling module; and
an operations module having operable equipment to be cooled by the cryogenic module,
wherein the first interface is configured to connect and disconnect the cryogenic module to/from the pre-cooling module while the pre-cooling module is in an on-state or idle state, and
wherein the second interface is configured to connect and disconnect the cryogenic module to/from the operations module while the cryogenic module is in an on-state or idle state.

8. The modular cryogenic infrastructure of claim 7, wherein the cryogenic module comprises a plurality of cryogenic modules that are connectable in parallel to the pre-cooling module.

9. The modular cryogenic infrastructure of claim 7, wherein the operations module comprises a plurality of operations modules that are connectable to each other via respective interfaces.

10. The modular cryogenic infrastructure of claim 7, wherein the cryogenic module comprises a first cryogenic module and a second first cryogenic module and the operation module comprises a first operations module and a second operations module, the first operations module being connectable to the first cryogenic module, and the second operations module being connectable to the second cryogenic module.

11. The modular cryogenic infrastructure of claim 7, wherein the operation module comprises a first operations module and a second operations module, the first operations module being connectable to the cryogenic module, and the second operations module being connectable to the first operations module while being not connected to the cryogenic module.

12. The modular cryogenic infrastructure of claims 7, wherein the operations module comprises a module selected from a group consisting of a quantum technology module, a quantum computing module, a quantum communications module, a quantum sensing module, an optics module, an adiabatic demagnetization refrigeration module, and any combinations thereof.

13. The modular cryogenic infrastructure of claims 7, wherein the pre-cooling module comprises a centralized pre-cooling module and/or a Turbo-Brayton cooling module.

14. The modular cryogenic infrastructure of claims 7, wherein the operations module is configured to provide a thermal path between the pre-cooling module and the cryogenic module to provide pre-cooling to the cryogenic modules.

15. The method of operating a modular cryogenic infrastructure, comprising:
providing a cryogenic module having a first interface and a second interface at an exterior of the cryogenic module;
using the first interface to connect and disconnect the cryogenic module to/from a pre-cooling module while the pre-cooling module is in an on-state or idle state; and
using the second interface to connect and disconnect the cryogenic module to/from an operations module having operable equipment to be cooled by the cryogenic module while the cryogenic module is in an on-state or idle state.

16. The method of claim 15, further comprising pre-cooling module the cryogenic module with the pre-cooling module when the first interface connects the cryogenic module to the pre-cooling module.

17. The method of claim 15, further comprising using the first interface to connect and disconnect the cryogenic module to/from the pre-cooling module while the cryogenic module is in an off-state.

18. The method of claim 15, wherein the step of providing the cryogenic module comprises providing a plurality of cryogenic modules, wherein the method further comprises connecting the plurality of cryogenic modules to the pre-cooling module in parallel.

19. The method of claim 15, wherein the step of providing the operations module comprises providing a plurality of operation modules, wherein the method further comprises connecting the plurality of operation modules to each other via respective interfaces.

20. The method of claim 15, further comprising using the second interface to connect and disconnect the cryogenic module to/from the operations module while using the first interface to connect the cryogenic module to the pre-cooling module.
